(19) United States
(12) Patent Application Publication
(10) Pub. No.: US 2013/0271306 A1
(43) Pub. Date: Oct. 17, 2013

(54) APPARATUS AND METHOD FOR COLLECTING DATA AT MULTI-POINTS

(71) Applicants: In Su Jang, Seoul (KR); Seong Hoon Choi, Seoul (KR); Jang Hyun Park, Seoul (KR); Chang Beom Kim, Seoul (KR); Ji Hun Eo, Gyeongsangbuk-do (KR); Jae Dong Lee, Chungcheongbuk-do (KR); Yong Hwan Lee, Gyeonggi-do (KR); Young Chan Jang, Gyeongsangbuk-do (KR)

(72) Inventors: In Su Jang, Seoul (KR); Seong Hoon Choi, Seoul (KR); Jang Hyun Park, Seoul (KR); Chang Beom Kim, Seoul (KR); Ji Hun Eo, Gyeongsangbuk-do (KR); Jae Dong Lee, Chungcheongbuk-do (KR); Yong Hwan Lee, Gyeonggi-do (KR); Young Chan Jang, Gyeongsangbuk-do (KR)

(73) Assignees: Kumoh National Institute of Technology Industry-Academic Cooperation Foundation, Gumi (KR); Electronics and Telecommunications Research Institute, Daejeon (KR)

(21) Appl. No.: 13/602,770

(22) Filed: Sep. 4, 2012

(30) Foreign Application Priority Data
Apr. 16, 2012 (KR) 10-2012-0039279

(51) Int. Cl. H03M 1/12

(52) U.S. Cl. 341/155

(57) ABSTRACT

The present invention, which relates to an apparatus for collecting data at multi-points, suggests an apparatus connecting analog blocks obtaining the same channel data in series with each other and connecting analog blocks obtaining different channel data in parallel with each other to collect data. The suggested apparatus includes a channel data collecting group including at least two channel data collecting units having data obtaining modules collecting channel data at different points and connected in series with each other; and a channel data processing unit including the channel data collecting units connected in parallel with each other and controlling each of the data obtaining module so as to allow each of the channel obtaining module to shift the channel data by a predetermined size.

### CROSS-REFERENCE TO RELATED APPLICATIONS

This application claims priority to and the benefit of Korean Patent Application No. 10-2012-0039279 filed in the Korean Intellectual Property Office on Apr. 16, 2012, the entire contents of which are incorporated herein by reference.

### TECHNICAL FIELD

The present invention relates to an apparatus and method for collecting channel data. More particularly, the present invention relates to an apparatus and method for collecting channel data at multi-points.

### BACKGROUND ART

An apparatus for obtaining data at multi-points according to the related art includes a plurality of analog blocks positioned at each point and a digital block. This apparatus transmits data obtained from the analog blocks to the digital block to process the data.

However, for data transmission between the analog blocks configured of the multi-points and the digital block, a plurality of control signals and output signals should be connected to each other. Therefore, in this apparatus, each analog block is directly connected to the digital block. However, this connection may increase loads of the analog blocks and the digital block. A structure of an interface configured of the analog blocks and the digital block may become complicated.

### SUMMARY OF THE INVENTION

The present invention has been made in an effort to provide an apparatus and method for collecting data by connecting analog blocks obtaining the same channel data in series with each other and connecting analog blocks obtaining different channel data in parallel with each other.

An exemplary embodiment of the present invention provides an apparatus for collecting data at multi-points, the apparatus including: a channel data collecting group including at least two channel data collecting units having data obtaining modules collecting channel data at different points and connected in series with each other; and a channel data processing unit including the channel data collecting units connected in parallel with each other and controlling each of the data obtaining module so as to allow each of the channel obtaining module to shift the channel data by a predetermined size.

Each of the data obtaining modules may include: a data converter converting channel data in an analog signal format into a digital signal; and a data shifter storing the digital signal and shifting the digital signal to other data obtaining module connected in series or the channel data processing unit according to a control of the channel data processing unit.

The data shifter may shift the digital signal using a predetermined number of D flip-flops according to a ratio between the entire size of the channel data and a size of the shifted channel data.

Each of the data obtaining modules may further include an input selector selecting one input signal among different input signals as the analog signal for digital conversion according to the control of the channel data processing unit.

The data processing unit may include: a control signal generator generating a control signal for controlling each of the data obtaining modules and applying the generated control signal to each of the data obtaining modules; a data storage extracting channel data shifted according to application of the control signal from the channel data input from the channel data collecting group to store the extracted channel data therein; and a data reading controller controlling an external device to read the stored channel data according to a predetermined reference when a read request for the stored channel data is received.

The control signal generator may select one channel data collecting unit among the channel data collecting units collecting different channel data and apply the control signal to data obtaining modules provided in the selected channel data collecting unit.

The channel data storage may include: a sequence storage sequentially storing extracted channel data from the most significant bit (MSB) whenever the shifted channel data are extracted; and a combination storage combining the sequentially stored channel data with each other to store the combined channel data.

The data obtaining modules provided in the same channel data collecting unit may collect the same channel data as each other, and the channel data collecting units may collect different channel data.

The channel data processing unit may control all of the data obtaining modules provided in the channel data collecting unit, when the channel data processing unit controls each of the data obtaining modules.

The apparatus for collecting data at multi-points may be used to measure brain wave signals having a different shape.

Another exemplary embodiment of the present invention provides a method for collecting data at multi-points, the method including: a channel data collecting step of collecting channel data at different points using data obtaining modules of channel data collecting units including the data obtaining modules connected in series with each other and controlling each of the data obtaining module of the channel data collecting unit connected in parallel with each other to shift the channel data by a predetermined size; and a channel data processing step of collecting the shifted channel data to store the collected channel data.

The channel data collecting step may include: a data converting step of converting channel data in an analog signal format collected at different points into digital signals; and a data shifting step of storing the digital signals and shifting the digital signals.

In the data shifting step, the digital signal may be shifted using a predetermined number of D flip-flops according to a ratio between the entire size of the channel data and a size of the shifted channel data.

The channel data collecting step may further include an input selecting step of controlling each of the data obtaining modules to select one input signal as an analog signal for digital conversion among different input signals. The input selecting step may be performed before the data converting step.

The channel data collecting step may further include a control signal generating step of generating the control signal controlling each of the data obtaining module and applying the control signal to each of the data obtaining module. The control signal generating step may be performed before the input selecting step.

The channel data processing step may include: a channel data storing step of extracting only channel data shifted according to application of the control signal from the input channel data to store the extracted data; and a data reading controlling step of controlling an external device to read the stored channel data according to a predetermined reference when a read request for the stored channel data is received.

In the control signal generating step, one channel data collecting unit may be selected among the channel data collecting units collecting different channel data, and the control signal may be applied to the data obtaining modules provided in the selected channel data collecting unit.

The channel data storing step may include: a sequence storing step of sequentially storing the shifted channel data from the most significant bit (MSB) whenever the shifted channel data are extracted; and a combination storing step of combining the sequentially stored channel data to store the combined data.

In the channel data collecting step, when the channel data is collected, the same channel data may be collected using the data obtaining modules provided in the same channel data collecting unit, and different channel data may be collected using the channel data collecting units.

In the channel data collecting step, when each of the data obtaining modules are controlled, all of the data obtaining modules provided in the channel data collecting unit may be controlled.

The method for collecting data at multi-points described above may be used to measure brain wave signals having a different shape.

The present invention suggests the apparatus and method for collecting data connecting the analog blocks obtaining the same channel data in series with each other and connecting the analog blocks obtaining different channel data in parallel with each other, thereby making it possible to obtain the following effects. First, the number of data lines between the analog blocks and the digital block is reduced, such that the loads of the analog blocks may be reduced. Second, the control signal by the digital block is shared in each channel, such that the load of the digital block may be reduced. Third, the structure of the interface configured of the analog blocks and the digital block may be simplified. Fourth, the multi-channel data may be collected at the multi-points.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a block diagram schematically showing an apparatus for collecting data at multi-points according to an exemplary embodiment of the present invention.

FIGS. 2 and 3 are block diagrams showing in detail an internal configuration of the apparatus for collecting data at multi-points shown in FIG. 1.

FIG. 4 is an exemplary diagram of the apparatus for collecting data at multi-points shown in FIG. 1.

FIG. 5 is an exemplary diagram of an apparatus for collecting data at multi-points suggested in order to measure brain wave signals.

FIG. 6 is an internal configuration diagram of a module configuring a digital interface system shown in FIG. 4.

FIG. 7 is an internal configuration diagram of a digital block configuring a digital interface system shown in FIG. 4.

FIG. 8 is a timing diagram for transmitting MEG signals from each of the modules to the digital block in the digital interface system shown in FIG. 5.

FIG. 9 is a flow chart schematically showing a method for collecting data at multi-points according to an exemplary embodiment of the present invention.

It should be understood that the appended drawings are not necessarily to scale, presenting a somewhat simplified representation of various features illustrative of the basic principles of the invention. The specific design features of the present invention as disclosed herein, including, for example, specific dimensions, orientations, locations, and shapes will be determined in part by the particular intended application and use environment.

In the figures, reference numbers refer to the same or equivalent parts of the present invention throughout the several figures of the drawing.

### DETAILED DESCRIPTION

Hereinafter, exemplary embodiments of the present invention will be described in detail with reference to the accompanying drawings. First, it is to be noted that in giving reference numerals to components of each of the accompanying drawings, like reference numerals refer to like components even though like components are shown in different drawings. In describing the exemplary embodiments of the present invention, well-known functions or constructions will not be described in detail since they may unnecessarily obscure the understanding of the present invention. Although the exemplary embodiments of the present invention will be described below, the scope of the present invention is not limited thereto, but may be variously changed by those skilled in art.

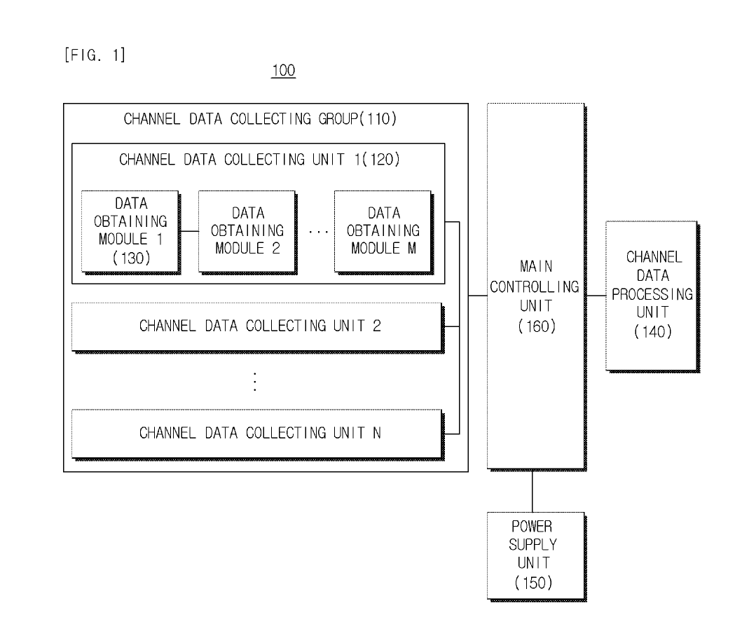

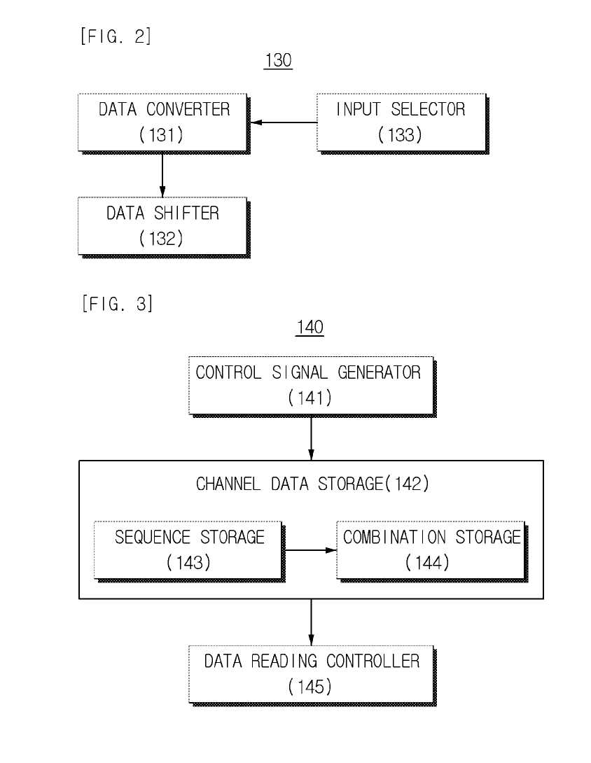

FIG. 1 is a block diagram schematically showing an apparatus for collecting data at multi-points according to an exemplary embodiment of the present invention. FIGS. 2 and 3 are block diagrams showing in detail an internal configuration of the apparatus for collecting data at multi-points shown in FIG. 1. Hereinafter, a description thereof will be provided with reference to FIGS. 1 to 3.

Referring to FIG. 1, an apparatus 100 for collecting data at multi-points includes a channel data collecting group 110, a channel data processing unit 140, a power supply unit 150, and a main controlling unit 160.

The apparatus 100 for collecting data at multi-points may be used to measure brain wave signals having a different shape. For example, the apparatus 100 for collecting data at multi-points may be used to measure electro-encephalography (EGG) signals and magneto-encephalography (MEG) signals as the brain wave signals having different shapes.

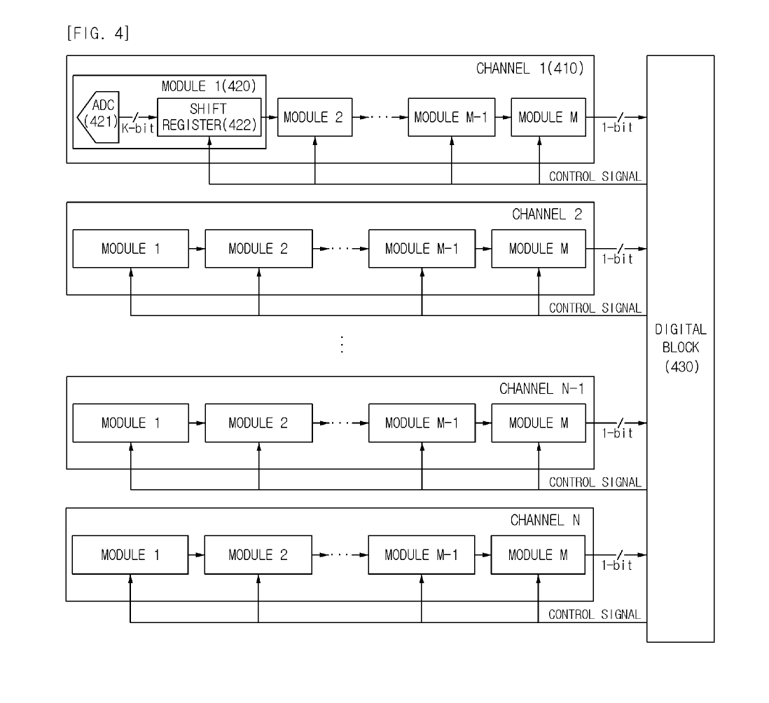

The channel data collecting group 110 includes at least two channel data collecting units 120 including data obtaining modules 130 for collecting channel data at different points from each other, wherein the data obtaining modules 130 are connected in series with each other. The data obtaining modules 130 provided in the same channel data collecting unit 120 may collect the same channel data as each other, and the channel data collecting units 120 may collect different channel data. The data obtaining modules 130 indicate M modules to be described below with reference to FIGS. 4 to 8. The channel data collecting units 120 indicate N channels to be described below with reference to FIGS. 4 to 8.

The data obtaining module 130 may include a data converter 131 and a data shifter 132 as shown in FIG. 2.

The data converter 131 converts channel data in an analog signal format into a digital signal. The data converter indicates an analog-digital converter (ADC) to be described below with reference to FIGS. 4 to 8.

The data shifter 132 stores the digital signal and shifts the digital signal to other data obtaining module connected in series or the channel data processing unit 140 according to a control of the channel data processing unit 140. The data shifter 132 shifts the digital signal using a predetermined number of D flip-flops according to a ratio between the entire size of the channel data and a size of the shifted channel data. For example, if the data shifter 132 is an 8-bit shift register, the data shifter 132 may be composed of eight D flip-flops. The data shifter 132 indicates a shift register to be described below with reference to FIGS. 4 to 8.

The data obtaining module 130 may further include an input selector 133 as shown in FIG. 2.

The input selector 133 selects one input signal among different input signals as the analog signal for digital conversion according to the control of the channel data processing unit 140.

The channel data processing unit 140 is connected to the channel data collecting units 120 in parallel and controls each of the data obtaining modules 130 so as to allow each of the data obtaining modules 130 to shift the channel data by a predetermined size. For example, the channel data processing unit 140 may control the data obtaining module 130 so that the channel data are shifted bit by bit. The channel data processing unit 140 may control the data obtaining module 130 so that the channel data are delayed. Meanwhile, when the channel data processing unit 140 controls each of the data obtaining modules 130, the channel data processing unit 140 may control all of the data obtaining modules 130 provided in the channel data collecting unit 120. The channel data processing unit 140 indicates a digital block to be described below with reference to FIGS. 4 to 8.

The channel data processing unit 140 may include a control signal generator 141, a channel data storage 142, and a data reading controller 145, as shown in FIG. 3.

The control signal generator 141 generates the control signal for controlling each of the data obtaining modules and applies the generated control signal to each of the data obtaining modules 130. The control signal generator 141 may select one channel data collecting unit among the channel data collecting units collecting different channel data and apply the control signal to data obtaining modules provided in the selected channel data collecting unit. The control signal generator 141 indicates a serial to parallel (STL) finite state machine (FSM) to be described below with reference to FIGS. 4 to 8.

The channel data storage 142 extracts only channel data shifted according to application of the control signal from the channel data input from the channel data collecting group 110 to store the extracted channel data therein.

The channel data storage 142 may include a sequence storage 143 and a combination storage 144.

The sequence storage 143 sequentially stores the extracted channel data from the most significant bit (MSB) whenever the shifted channel data are extracted. The sequence storage 143 indicates a shift register to be described below with reference to FIGS. 4 to 8. The most significant bit means MSB.

The combination storage 144 combines the sequentially stored channel data with each other to store the combined channel data. The combination storage 144 indicates a register REG to be described below with reference to FIGS. 4 to 8.

The data reading controller 145 controls an external device to read the stored channel data according to a predetermined reference when a read request for the stored channel data is received. The data reading controller 145 indicates a configuration in which first-in first-out (FIFO) and FIFP computational tree logic (CTL) finite state machines (FSM) to be described below with reference to FIGS. 4 to 8 are coupled to each other.

The power supply unit 150 supplies power to each of the configurations configuring the apparatus 100 for collecting data at multi-points.

The main controlling unit 160 controls the entire operations of each of the configurations configuring the apparatus 100 for collecting data at multi-points.

Next, as an example of the apparatus 100 for collecting data at multi-points, a digital interface system for obtaining data at multi-points will be described. FIG. 4, which is an exemplary diagram of the apparatus 100 for collecting data at multi-points shown in FIG. 1, is the entire block diagram implemented in a serial/parallel interface structure between multi-points configured of M×N modules and a digital block.

The present invention relates to the serial/parallel interface structure between the multi-points configured of the M×N modules and the digital block for obtaining data of the multi-points. According to the exemplary embodiment of the present invention, a complicated structure for data processing may be solved by reducing the number of data lines and loads of the channel and the module. The present invention has the serial/parallel interface structure in order to obtain data at the multi-points as shown in FIG. 4. In order to transmit data of each of the modules 420 to a digital block 430 bit by bit to sequentially process the data, M modules are connected in series with each other. Through this configuration, the number of data lines is reduced, and a common bus structure is removed, thereby reducing a load of a data channel. To this end, each of the modules 420 includes a shift register 422 to shift the data according to a common clock signal and control signal, thereby performing the serial interface. In order to share the clock signal and the control signal CS in each channel 410 to decrease the loads by the signals and increase data obtaining points of the entire system, the apparatus 100 for collecting data at multi-points has a structure in which N channels are connected in parallel with each other.

In order to obtain signals and data at M×N points, the respective points have a separate module in order to perform several functions, as shown in FIG. 4. The respective modules are connected to each other using a serial structure for a single channel and a parallel data line having a multi-channel. Data lines of the modules present in a single channel are connected in series with each other. To this end, first, a signal to be output in each of the module is converted into k bits of digital signal by an analog digital converter (ADC) 421. In order to output the k bits of converted digital signal through the data line, a k-bit shift register 422 is demanded, and this k-bit shift register 422 is positioned in series between an input and an output in each of the module.

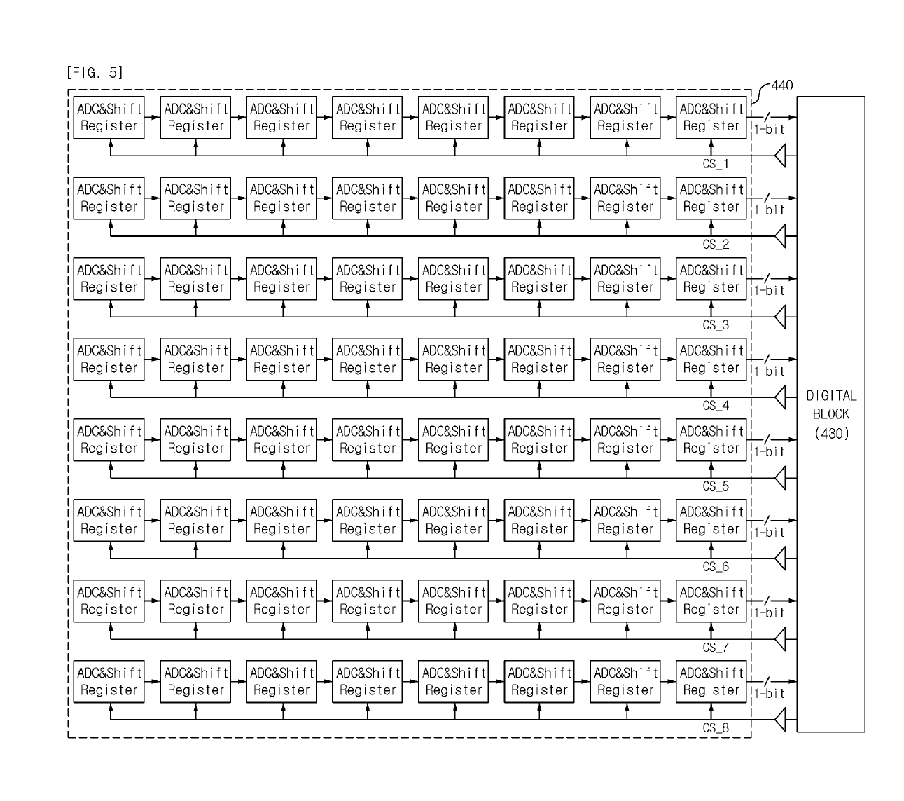

FIG. 5, which is an exemplary diagram of an apparatus for collecting data at multi-points in order to measure brain wave signals, is a structural diagram of a serial/parallel interface between multi-points 440 configured of 8×8 modules and a digital block 430.

A system having 8×8 multi-points 440 in order to obtain data of magneto-encephalography (MEG) signals and electro-encephalography (EGG) signals that are human brain wave signals is shown in FIG. 5. In order to efficiently obtain data from the multi-points 440 to transfer the obtained data to the digital block 430, a digital interface system and circuit having a serial/parallel structure may be formed as shown in FIG. 5.

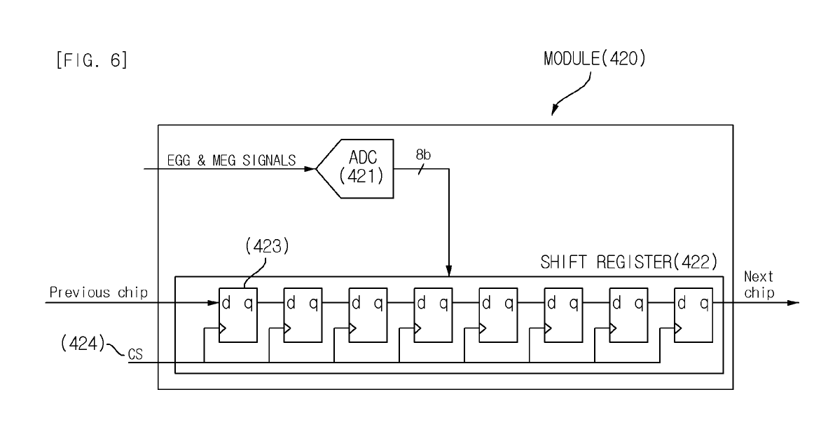

FIG. 6 is an internal configuration diagram of a module configuring a digital interface system shown in FIG. 4. The module 420 for obtaining the data at each point includes an eight-bit ADC 421 and an eight-bit shift register 422 configured of eight D flip-flops 423 in order to process the EEG signal and the MEG signal.

The ADC 421 selects the EEG signal or the MEG signal to receive the selected signal as an input and then converts the received signal into eight bits of digital code. The converted digital code is stored in the shift register 422 configured of the eight D flip-flops 423 at a first cycle of a control signal (CS) 424 applied from the digital block so as to be transmitted to the digital block. The data stored in the shift register 422 are shifted to the digital block bit by bit at and after a second cycle of the CS signal 424. As a result, the data of the EEG or the MEG are sequentially transmitted to the digital block bit by bit.

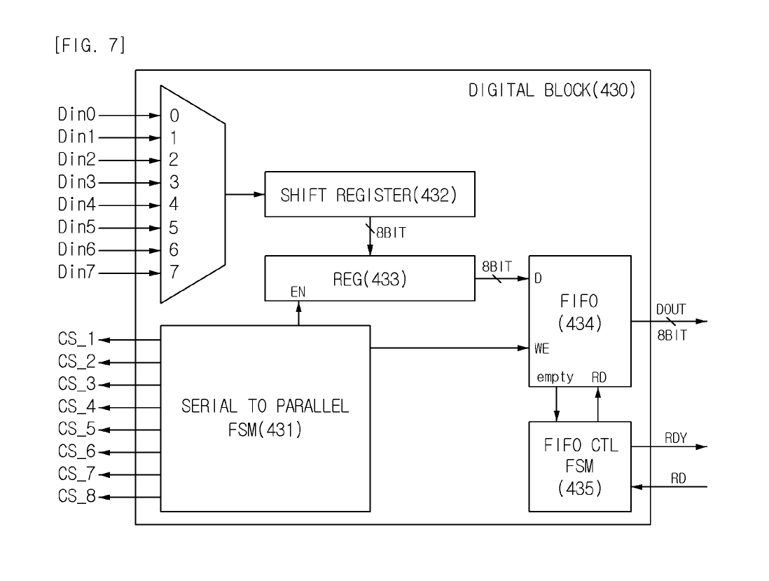

FIG. 7 is an internal configuration diagram of a digital block configuring a digital interface system shown in FIG. 4. An operation method of the digital block 430 is as follows.

First, a serial to parallel FSM 431 generates the control signal (CS) that is a serial control signal to apply the generated CS to the ADC of each of the module. Then, each of the modules converts the analog input signal into the digital code, stores the converted digital code in the shift register, and transmits the data to the digital block 430 bit by bit. The data transmitted to the digital block 430 through each of the modules as described above are input as Din0 to Din7. The shift register 432 of the digital block 430 stores only the data selected by the serial to parallel FSM 431 (that is, the data sequentially shifted bit by bit) among the data of the Din0 to Din7, from an MSB. Eight bits of data are again stored in a REG 433. In the case in which an external device asynchronously reads the data stored in the REG 433, the digital block 430 buffers the data using an FIFO 434. At this time, when a RDY signal is activated in an FIFO CTL FSM 435, the external device may read the data using a RD signal.

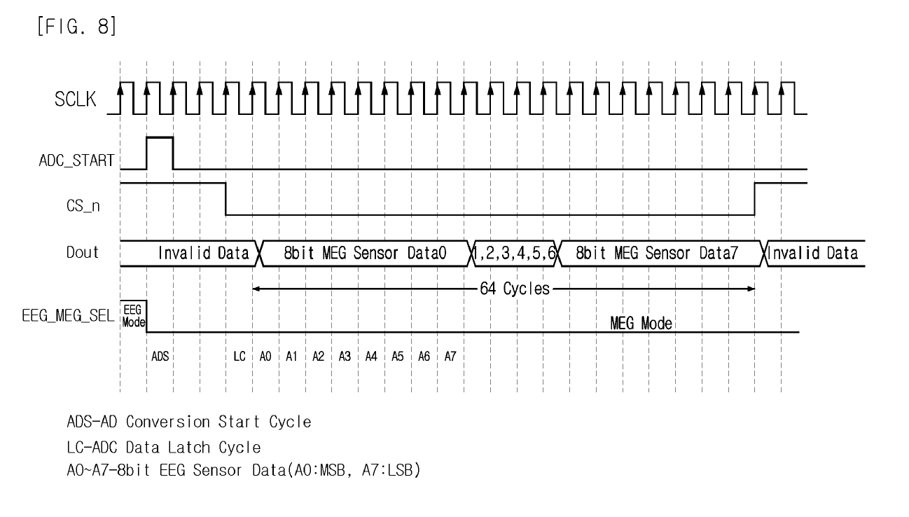

FIG. 8 is a timing diagram for transmitting a MEG signal from each of the modules to the digital block in the digital interface system shown in FIG. 5.

FIG. 8 shows the timing diagram in order to transmit the MEG signal that is a human brain wave signal from the modules of the multi-points configured in the serial/parallel interface structure of FIG. 5 to the digital block. In order to obtain the data of the MEG signal, signals of SCLK, ADC_START, and CS_n are required. The reason is that the SCLK is required to synchronize the ADC_START signal and the CS_n signal with each other. That is, the SCLK has a frequency of 16 kHz, and the ADC_START signal is enabled during one cycle of the SCLK. The ADC is operated only in the case in which the ADC_START signal is high to perform data conversion just once, thereby outputting the eight bits of digital code. Then, data of the channel selected by the first cycle signal of the CS_n is stored in the shift register configured of the eight D flip-flops, and the data are transmitted to the digital block bit by bit at and after a second cycle. Therefore, it may be confirmed through the timing diagram that 64 SCLK cycles are required in order to transmit a single channel data to the digital block. Dout is data transmitted from the module to the digital block, and it may be appreciated that the Dout is configured of eight data each including a total of 8 bits.

The digital interface system described above may reduce the number of data lines used in order to obtain data of the block configured of the modules of the multi-points through the suggested serial/parallel interface structure. The data of the module are transmitted to the digital block through the shift register bit by bit, such that data are sequentially processed, thereby making it possible to reduce the load of the module. The digital interface system is configured of N channels, such that the loads of the clock signal and the control signal CS shared in one channel may be reduced. A main configuration of the digital interface system described above will be arranged as follows.

\textcircled{1} the serial/parallel interface structure for obtaining signals and data of M×N multi-points
the channel structure in which M modules are connected in series with each other
the serial channel structure in which an output of the previous end is connected to an input of the current end in the M modules connected in series with each other.
the structure in which the control signal CS for each of the module is shared with each other in one channel
N parallel channels for reducing the loads of the clock signal and the control signal
the digital block structure for receiving the data from the M×N modules

\textcircled{2} the structure of each of the module for using the digital interface structure
the analog-digital converter (k-bit ADC)
the k-bit shift register for storing the k bits of digital signal and supporting the serial interface
a structure in which input and output modules of the k-bit shift register are connected to the outside
the structure of the register synchronized with an external signal CS of the module to shift the data

\textcircled{3} the digital block structure for receiving the data from the M×N modules
M modules in a single channel and the shift register and the register structure for processing k bits of serial data per each module
the FSM and the data selector selecting a parallel channel and generating CS in order to synchronize data

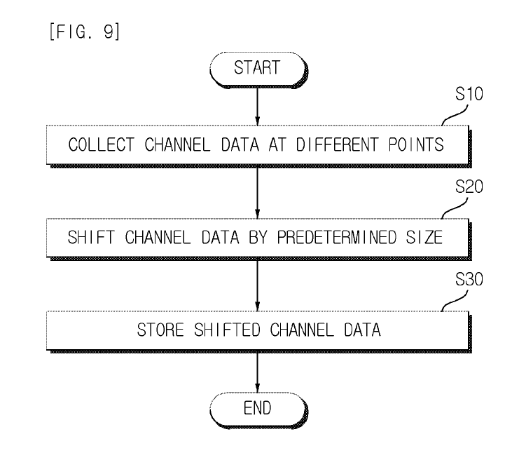

Next, a method for collecting data at multi-points in the apparatus for collecting data at multi-points will be described. FIG. 9 is a flow chart schematically showing a method for collecting data at multi-points according to an exemplary embodiment of the present invention. Hereinafter, a description will be provided with reference to FIG. 9.

First, channel data collecting units including data obtaining modules connected in series with each other collect channel data at different points using the data obtaining modules (S10). At the time of collecting of the channel data, the data obtaining modules provided in the same channel data collecting unit may collect the same channel data as each other, and the channel data collecting units may collect different channel data, respectively.

Then, each of the data obtaining modules of the channel data collecting units connected in parallel with each other shifts the channel data by a predetermined size according to a control of a channel data processing unit (S20).

Step S20 may be subdivided as follows. First, a data converter converts channel data in an analog signal format collected at different points into digital signals. Next, a data shifter stores the digital signal and shifts the stored digital signal. The data shifter may shift the digital signal using a predetermined number of D flip-flops according to a ratio between the entire size of the channel data and a size of the shifted channel data.

Meanwhile, step S20 may be subdivided to further include an input selecting step. At this step, an input selector controls each of the data obtaining modules to select one input signal among different input signals as an analog signal for digital conversion. The input selector performs this step before the data converter is driven.

Meanwhile, step S20 may be subdivided to further include a control signal generating step. At this step, a control signal generator generates the control signal in order to control each of the data obtaining modules and applies this control signal to each of the data obtaining modules. The control signal generated by the control signal generator is used to control each of the data obtaining modules of the channel data collecting unit. The control signal generator performs this step before the input selector is driven. Here, when the channel data processing unit controls each of the data obtaining modules, it may control all of the data obtaining modules provided in the channel data collecting unit.

The control signal generator may select one channel data collecting unit among the channel data collecting units collecting different channel data and apply the control signal to the data obtaining modules provided in the selected channel data collecting unit.

After step S20, the channel data processing unit collects the shifted channel data to store the collected channel data (S30).

Step S30 may be subdivided as follows. First, a channel data storage extracts the channel data shifted according to application of the control signal from the input channel data to store the extracted data. The channel data storage may sequentially store the extracted channel data from the MSB whenever the shifted channel data are extracted, and combine the sequentially stored channel data to each other to store the combined channel data. Then, the data reading controller controls an external device to read the stored channel data according to a predetermined reference when a read request for the stored channel data is received.

As described above, the exemplary embodiments have been described and illustrated in the drawings and the specification. The exemplary embodiments were chosen and described in order to explain certain principles of the invention and their practical application, to thereby enable others skilled in the art to make and utilize various exemplary embodiments of the present invention, as well as various alternatives and modifications thereof. As is evident from the foregoing description, certain aspects of the present invention are not limited by the particular details of the examples illustrated herein, and it is therefore contemplated that other modifications and applications, or equivalents thereof, will occur to those skilled in the art. Many changes, modifications, variations and other uses and applications of the present construction will, however, become apparent to those skilled in the art after considering the specification and the accompanying drawings. All such changes, modifications, variations and other uses and applications which do not depart from the spirit and scope of the invention are deemed to be covered by the invention which is limited only by the claims which follow.

What is claimed is:

1. An apparatus for collecting data at multi-points, the apparatus comprising:
a channel data collecting group including at least two channel data collecting units having data obtaining modules collecting channel data at different points and connected in series with each other; and
a channel data processing unit including the channel data collecting units connected in parallel with each other and controlling each of the data obtaining module so as to allow each of the channel obtaining module to shift the channel data by a predetermined size.

2. The apparatus of claim 1, wherein the data obtaining module includes:
a data converter converting channel data in an analog signal format into a digital signal; and
a data shifter storing the digital signal and shifting the digital signal to other data obtaining module connected in series or the channel data processing unit according to a control of the channel data processing unit.

3. The apparatus of claim 2, wherein the data shifter shifts the digital signal using a predetermined number of D flip-flops according to a ratio between the entire size of the channel data and a size of the shifted channel data.

4. The apparatus of claim 2, wherein the data obtaining module further includes an input selector selecting one input signal among different input signals as the analog signal for digital conversion according to the control of the channel data processing unit.

5. The apparatus of claim 1, wherein the data processing unit includes:
a control signal generator generating a control signal for controlling each of the data obtaining modules and applying the generated control signal to each of the data obtaining modules;
a data storage extracting only channel data shifted according to application of the control signal from the channel data input from the channel data collecting group to store the extracted channel data therein; and
a data reading controller controlling an external device to read the stored channel data according to a predetermined reference when a read request for the stored channel data is received.

6. The apparatus of claim 5, wherein the control signal generator selects one channel data collecting unit among the channel data collecting units collecting different channel data and applies the control signal to data obtaining modules provided in the selected channel data collecting unit.

7. The apparatus of claim 5, wherein the channel data storage includes:
a sequence storage sequentially storing extracted channel data from the most significant bit (MSB) whenever the shifted channel data are extracted; and
a combination storage combining the sequentially stored channel data with each other to store the combined channel data.

8. The apparatus of claim 1, wherein the data obtaining modules provided in the same channel data collecting unit collect the same channel data as each other, and the channel data collecting units collect different channel data.

9. The apparatus of claim 1, wherein the channel data processing unit controls all of the data obtaining modules provided in the channel data collecting unit, when the channel data processing unit controls each of the data obtaining modules.

10. The apparatus of claim 1, wherein the apparatus for collecting data at multi-points is used to measure brain wave signals having a different shape.

11. A method for collecting data at multi-points, the method comprising:
a channel data collecting step of collecting channel data at different points using data obtaining modules of channel data collecting units including the data obtaining modules connected in series with each other and controlling each of the data obtaining module of the channel data collecting unit connected in parallel with each other to shift the channel data by a predetermined size; and
a channel data processing step of collecting the shifted channel data to store the collected channel data.

12. The method of claim 11, wherein the channel data collecting step includes:
a data converting step of converting channel data in an analog signal format collected at different points into digital signals; and
a data shifting step of storing the digital signals and shifting the digital signal.

13. The method of claim 12, wherein in the data shifting step, the digital signal is shifted using a predetermined number of D flip-flops according to a ratio between the entire size of the channel data and a size of the shifted channel data.

14. The method of claim 12, wherein the channel data collecting step further includes an input selecting step of controlling each of the data obtaining modules to select one input signal as an analog signal for digital conversion among different input signals.

15. The method of claim 11, wherein the channel data collecting step further includes:
a control signal generating step of generating the control signal controlling each of the data obtaining module and applying the control signal to each of the data obtaining module, and
the channel data processing step includes:
a channel data storing step of extracting only channel data shifted according to application of the control signal from the input channel data to store the extracted data; and
a data reading controlling step of controlling an external device to read the stored channel data according to a predetermined reference when a read request for the stored channel data is received.

16. The method of claim 15, wherein in the control signal generating step, one channel data collecting unit is selected among the channel data collecting units collecting different channel data, and the control signal is applied to the data obtaining modules provided in the selected channel data collecting unit.

17. The method of claim 15, wherein the channel data storing step includes:
a sequence storing step of sequentially storing the shifted channel data from the most significant bit (MSB) whenever the shifted channel data are extracted; and
a combination storing step of combining the sequentially stored channel data to store the combined data.
